(19) United States
(12) Patent Application Publication
(10) Pub. No.: US 2025/0015126 A1
(43) Pub. Date: Jan. 9, 2025

(54) Power Semiconductor Device and Method of Producing a Power Semiconductor Device

(71) Applicant: Infineon Technologies Austria AG, Villach (AT)

(72) Inventors: Tobias Nardmann, Dresden (DE); Viktoryia Lapidus, Munchen (DE); Frank Pfirsch, Munchen (DE); Alessio Scavuzzo, Milano (IT)

(21) Appl. No.: 18/890,970

(22) Filed: Sep. 20, 2024

(30) Foreign Application Priority Data
Sep. 22, 2003 (DE) 102023209310.3

(51) Int. Cl. H01L 29/06; H01L 27/02; H01L 29/66; H01L 29/739; H01L 29/78

(52) U.S. Cl. CPC H01L 29/0603; H01L 27/0266; H01L 29/66333; H01L 29/66712; H01L 29/7395; H01L 29/7802; H01L 29/0692

(57) ABSTRACT

A power semiconductor device includes: a semiconductor body with a drift region of a first conductivity type; a first load terminal at a first side of the semiconductor body; a second load terminal at a second side of the semiconductor body opposite the first side, the power semiconductor device configured to conduct a load current between the load terminals; a control terminal at the first side configured to receive a control signal for controlling the load current; within an active region at least partially surrounded by an edge termination region, first trenches laterally confining mesas for conducting the load current, having control trenches electrically connected to the control terminal, and arranged in accordance with a first average pitch; and in a region laterally overlapping the control terminal, second trenches arranged in accordance with a second average pitch different from the first average pitch and electrically connected to the control terminal.

### TECHNICAL FIELD

This specification refers to embodiments of a power semiconductor device and to embodiments of a method of producing a power semiconductor device.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device. The load current is typically conducted by means of an active region of the power semiconductor device. The active region is typically surrounded by an edge termination region, which is terminated by an edge of the chip.

In case of a controllable power semiconductor device, e.g., a transistor, the load current path may be controlled by means of an insulated electrode, commonly referred to as gate electrode. For example, upon receiving a corresponding control signal, e.g., from a driver unit via a control terminal of the device, the control electrode may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure.

Irrespective of whether or not the device exhibits an RC configuration, it is generally an aim to design a power semiconductor device such it exhibits a high robustness, i.e., in terms of electro static discharge, ESD.

A given ESD robustness can be required by customers. However, small chips often fail to provide a sufficient level of ESD robustness. Typical solutions to address this issue include increasing the chip size and/or changing the contact scheme of mesas and trenches in the active region. This may, however, result in higher costs or reduced device performance.

### SUMMARY

According to an embodiment, a power semiconductor device comprises: a semiconductor body with a drift region of a first conductivity type; a first load terminal at a first side of the semiconductor body; a second load terminal at a second side of the semiconductor body opposite to the first side, wherein the power semiconductor device is configured to conduct a load current between the first load terminal and the second load terminal; a control terminal at the first side configured to receive a control signal for controlling the load current; within an active region of the power semiconductor device at least partially surrounded by an edge termination region, first trenches laterally confining mesas for conducting the load current. The first trenches comprise control trenches electrically connected to the control terminal. The first trenches are arranged in accordance with a first average pitch. The device further comprises, in a region laterally overlapping the control terminal, second trenches, wherein the second trenches are arranged in accordance with a second average pitch different from the first average pitch and electrically connected to the control terminal.

According to an embodiment, a power semiconductor device comprises: a semiconductor body with a drift region of a first conductivity type; a first load terminal at a first side of the semiconductor body; a second load terminal at a second side of the semiconductor body opposite to the first side, wherein the power semiconductor device is configured to conduct a load current between the first load terminal and the second load terminal; a control terminal at the first side configured to receive a control signal for controlling the load current; within an active region of the power semiconductor device at least partially surrounded by an edge termination region, first trenches laterally confining mesas for conducting the load current. The first trenches comprise control trenches electrically connected to the control terminal. The first trenches are arranged in accordance with a first average pitch. The device further comprises, in a region laterally overlapping the edge termination region, second trenches, wherein the second trenches are arranged in accordance with a second average pitch different from the first average pitch and electrically connected to the control terminal. In other words, the second trenches may be arranged in the edge termination region and/or the region laterally overlapping the control terminal.

According to another embodiment, a method of producing a power semiconductor device comprises forming the following components: a semiconductor body with a drift region of a first conductivity type; a first load terminal at a first side of the semiconductor body; a second load terminal at a second side of the semiconductor body opposite to the first side, wherein the power semiconductor device is configured to conduct a load current between the first load terminal and the second load terminal; a control terminal at the first side configured to receive a control signal for controlling the load current; within an active region of the power semiconductor device at least partially surrounded by an edge termination region, first trenches laterally confining mesas for conducting the load current. The first trenches comprise control trenches electrically connected to the control terminal. The first trenches are arranged in accordance with a first average pitch. The device further comprises, in a region laterally overlapping the control terminal, second trenches, wherein the second trenches are arranged in accordance with a second average pitch different from the first average pitch and electrically connected to the control terminal.

In accordance with some embodiments described herein, a given ESD robustness is improved by adding specialized structures using chip space that is typically not used for this purpose, e.g., chip space below the control terminal (gate pad). There, a custom pitch and/or contact scheme different from the trenches in the cell field formed in the active region can be provided. These structures can be added only through slight layout changes, without adding extra process steps, in accordance with some embodiments.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1A schematically and exemplarily illustrates a horizontal projection of a power semiconductor device in accordance with one or more embodiments;

FIG. 1B schematically and exemplarily illustrates a vertical cross-section of the power semiconductor device at line C indicated in FIG. 1A in accordance with one or more embodiments;

FIG. 2 schematically and exemplarily illustrates a section B of the horizontal projection of FIG. 1A in more detail, in accordance with one or more embodiments;

FIG. 3 schematically and exemplarily illustrates a section A of the horizontal projection of FIG. 1A in more detail, in accordance with one or more embodiments;

FIG. 4 schematically and exemplarily illustrates a section of a vertical cross-section of a power semiconductor device in accordance with one or more embodiments; and

FIG. 5 schematically and exemplarily illustrates a section of a horizontal projections of a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., greater than 1 Ampere, e.g. up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor device described below may be a single semiconductor chip, e.g., exhibiting a stripe cell configuration (or a cellular/needle cell configuration) and can be configured to be employed as a power component in a low-, medium- and/or high voltage application.

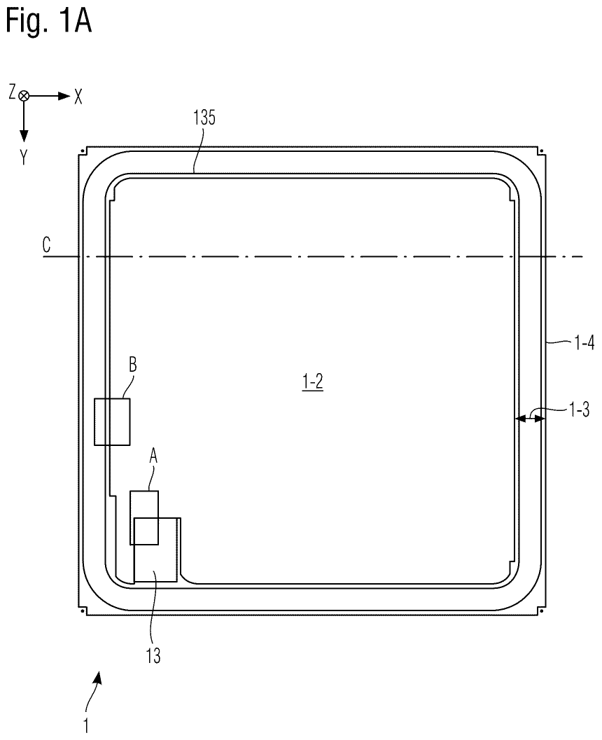

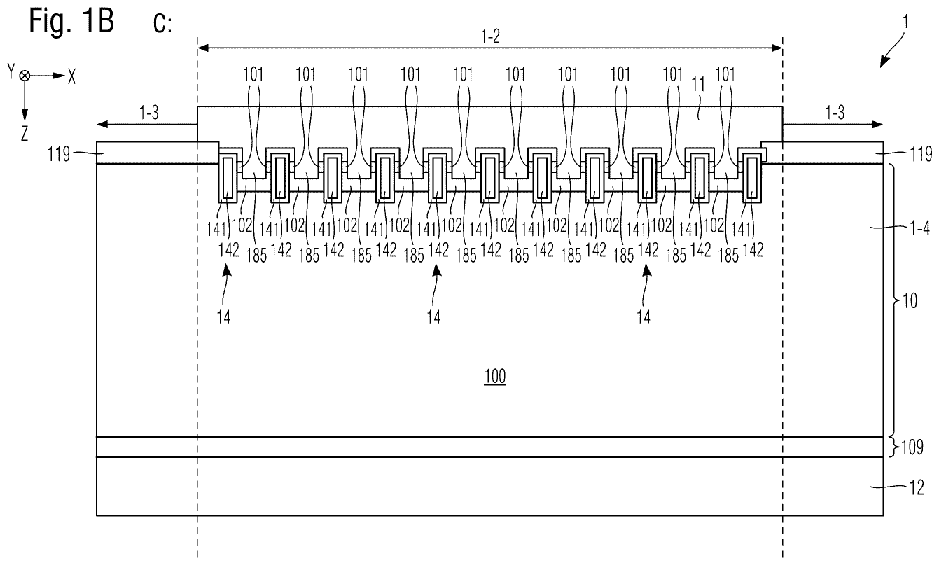

FIG. 1A schematically and exemplarily illustrates a horizontal projection of a power semiconductor device 1 in accordance with one or more embodiments. FIG. 1B schematically and exemplarily illustrates a vertical cross-section (at line C indicated in FIG. 1A) of the power semiconductor device 1 in accordance with one or more embodiments.

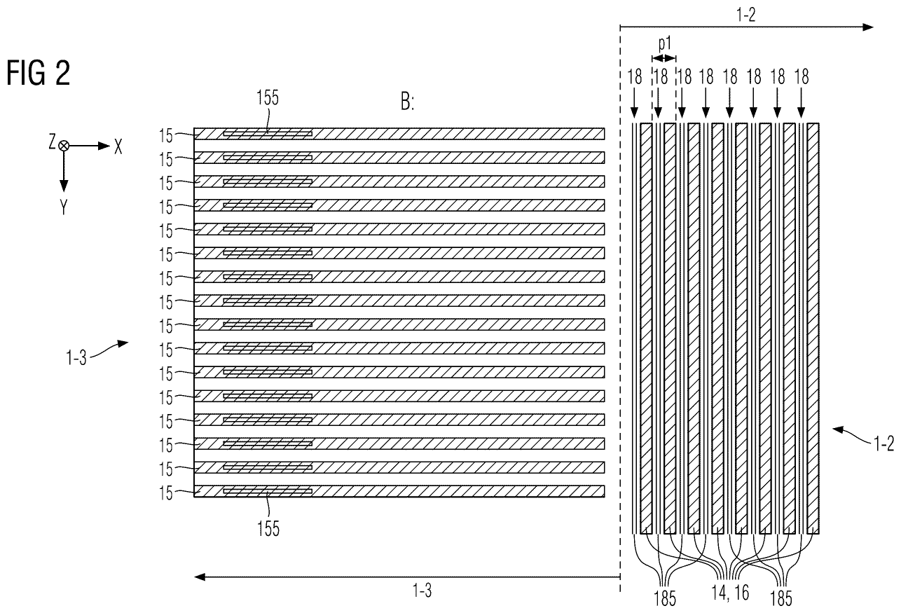

The following description will be better understood if additionally considering FIGS. 2 to 5, which will also be referred to in the following.

The power semiconductor device 1, herein also referred to as “device”, comprises, in a single chip, a semiconductor body 10 configured to conduct a load current between a first load terminal 11 at a first side 110 of the semiconductor body 10 and a second load terminal 12 at a second side 120 of the semiconductor body 10.

The first side 110 and the second side 120 may be arranged opposite of each other. E.g., the first side 110 is a front side of the device 1 and the second side 120 is a back side of the device 1. Accordingly, the device 1 may exhibit a vertical configuration according to which the load current within the device 1 follows a path in parallel to the vertical direction Z.

The device 1 further comprises a drift region 100 of a first conductivity type within the semiconductor body 10. Herein, the term “drift region” is employed with the meaning the skilled person typically associates therewith in the field of power semiconductor devices. For example, the vertical extension of the drift region 100 influences the voltage blocking capabilities of the device 1.

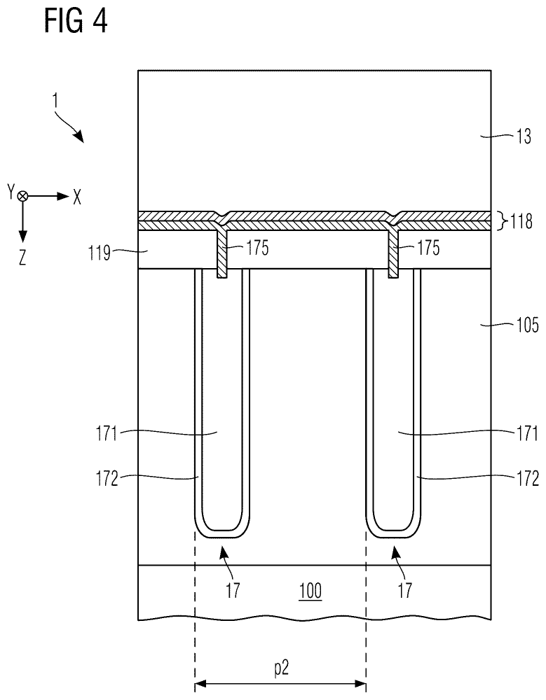

The device 1 further comprises first trenches 14 (and 16) and second trenches 17 extending from the first side 110 towards the second side 120, e.g., along the vertical direction Z. Each trench 14, 16, 17 includes a trench electrode separated from the semiconductor body 10 by a trench insulator (cf. exemplary cross-section in FIG. 4 illustrating the trench electrodes 171 of two of the second trenches 17 from the semiconductor body 10 by the trench insulator 172. The other trenches 14 and 16 may be configured identically.

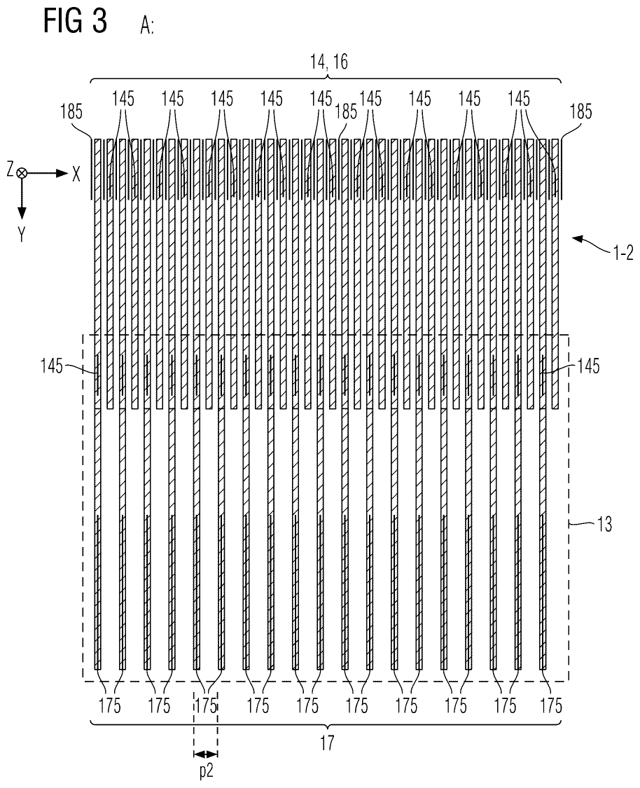

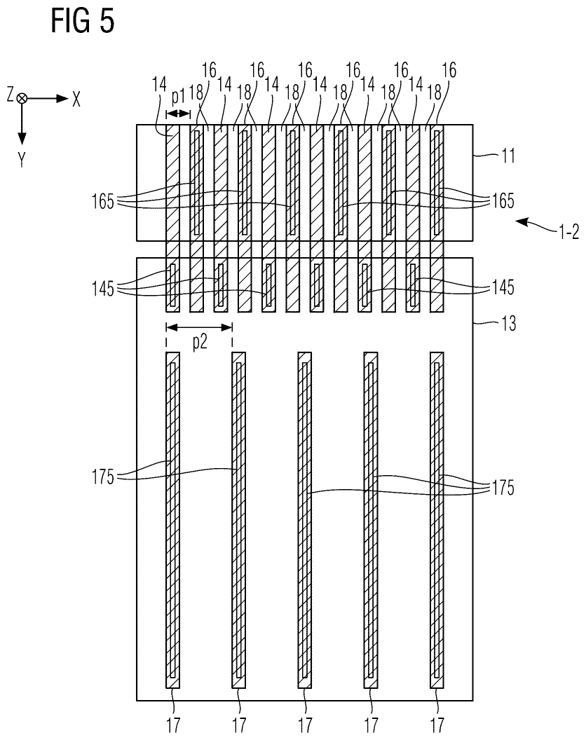

Said first trenches 14, 16 can comprise control trenches 14, wherein each trench electrode 141 of the control trenches 14 is electrically insulated from the first load terminal 11 and configured to receive a control signal. To this end, each trench electrode 141 of the control trenches 14 can be electrically connected to a control terminal 13 of the device 1, in accordance with an embodiment, e.g., via control trench contacts 145 (cf. FIGS. 3 and 5).

The control trenches 14 laterally confine mesas 18 of the semiconductor body 10. E.g., each mesa 18 is electrically connected to the first load terminal 11, e.g., by means of a respective mesa contact 185 extending from the first load terminal 11 into the semiconductor body 10, as exemplarily illustrated in FIG. 1B. Alternatively, a planar contact may be employed. Each mesa 18 may be configured for load current conduction. For example, each mesa 18 comprises a semiconductor body region 102 of the second conductivity type electrically connected to the first load terminal 11 and, optionally, a semiconductor source region 101 of the first conductivity type electrically connected to the first load terminal 11, wherein the semiconductor source region 101 is isolated from the drift region 100 by at least the semiconductor body region 102. The adjacent control trench electrode 141 may be configured to induce, upon being subject with a corresponding ON-control signal, an inversion channel in the semiconductor body region 102. This process may set the device 1 into the forward conducting state. The adjacent control trench electrode 141 may be configured to cut off, upon being subject with a corresponding OFF-control signal, said inversion channel in the semiconductor body region 102, which can set the device 1 into the forward blocking state.

The configuration illustrated in FIG. 1B is only exemplary. The above-described features of the power semiconductor device 1 may allow designing diverse trench-mesa-patterns at the first side 110. Such pattern may include further trench types and/or further mesa types, e.g., as part of the first trenches, source trenches 16 whose trench electrodes are electrically connected, e.g., via source trench contacts 165 (cf. FIG. 5) to the first load terminal 11, floating trenches whose trench electrodes are not connected with a defined electrical potential, or second type control trenches whose trench electrodes are connected to a different control terminal as compared to the control trench electrodes 141 to implement a dual or multi gate configuration and so on. Also, other type mesas may be implemented, e.g., those having a different threshold voltage, dummy mesa portions and so on.

A doped region 109 of the semiconductor body 10 below the drift region 100 adjoining the second load terminal 12 at the second side 120 can be configured in accordance with the designated characteristic of the device 1. E.g., the doped region 109 can be an emitter region of the second conductivity type, if the device 1 shall exhibit an IGBT configuration. The emitter region is arranged in contact with the second load terminal 12. In addition, a field stop region (not illustrated) of the first conductivity type can be provided between the drift region 100 and the second load terminal 12, wherein the field stop region exhibits a greater dopant concentration than the drift region 100. If the device 1 shall exhibit a MOSFET configuration, the emitter region is omitted such that the field stop region (or another highly doped region of the first conductivity type) would adjoin the second load terminal 12. If the device 1 shall exhibit an RC IGBT configuration, the emitter region may exhibit subsections of the first conductivity type, as it is known to the skilled person.

The above-described components of the power semiconductor device 1 are arranged in the active region 1-2 of the device 1, which is surrounded by an edge termination region 1-3. In the active region 1-2, the first trenches 14, 16 and the associated mesas 18 may form a cell field, which may exhibit a cellular/needle cell configuration or a stripe cell configuration. The edge termination region 1-3 is typically not employed for load current conduction, as it is known to the skilled person. The edge termination region 1-3 is terminated by the chip edge 1-4.

For example, referring to FIG. 2 illustrating section B indicated in FIG. 1A in more detail, third trenches 15 may be arranged in the edge termination region 1-3. Also these third trenches 15 may comprise insulated trench electrodes that may be electrically connected to a defined electrical potential, e.g., via third trench contacts 155, e.g., with the control terminal 13.

The third trenches 15 in the edge termination region 1-3 may extend perpendicular to the first trenches 14, 16 in the active region 1-2, in accordance with an embodiment. The third trenches 15 in the edge termination region 1-3 are separated from the first trenches 14, 16 in the active region 1-2, in accordance with an embodiment.

To facilitate distribution of the electrical potential of the control terminal 13, the device 1 may comprise a gate runner 135 that extends from the control terminal 13 along the circumference of the active region 1-2. The gate runner is electrically connected to the control terminal 13.

For example, referring to FIG. 3 illustrating section A indicated in FIG. 1A in more detail, the device 1 may comprise second trenches 17 in a region laterally overlapping the control terminal 13. The second trenches 17 (cf. FIG. 4) may comprise second trench electrodes 171 insulated from the semiconductor body 10 via second trench insulators 172 and electrically connected with the control terminal 13, e.g., via second trench contacts 175. The second trenches 17 may be inactive trenches and not be configured to induce an inversion channel. For example, the second trenches 17 are not arranged next to a source region 101. The region laterally overlapping the control terminal 13 may not be considered as part of the active region 1-2 within the scope of this application, as this region is not or not significantly contributing to a forward load current of the device 1.

An insulation structure 119 (cf. FIG. 1B and FIG. 4) may separate the terminal structure comprising the control terminal 13 and the first load terminal 11 from the semiconductor body 10. This insulation structure 119 may be locally penetrated via the mesa contacts 185 (connecting the mesas 18 to the first load terminal 11), the source trench contacts 165 (connecting the source trenches 16 to the first load terminal 11), the control trench contacts 145 (connecting the control trench electrodes 141 to the control terminal 13) and the second trench contacts 175 (connecting the second trench electrodes 171 to the control terminal 13).

Each of the trenches 14, 15, 16, 17 may exhibit a stripe configuration, in accordance with an embodiment. For example, according to the stripe configuration, the length of the trenches is significantly greater than the width of the trenches, as best illustrated in each of FIGS. 2, 3 and 5.

As illustrated in FIG. 1A, the control terminal 13 is arranged at the first side 110 and can be configured as a gate pad having a plate like geometry. The total lateral cross-sectional area of the control terminal 13 (and, correspondingly, of the chip region laterally overlapping therewith) may amount to a least 1%, or to at least 3% of the total lateral cross-sectional area of the active region 1-2. Said total lateral cross-sectional area of the control terminal 13 e.g. amounts to no more than 25% of the total lateral cross-sectional area of the active region 1-2. Further, the control terminal 13 may at least partially be surrounded by the active region 1-2.

The second trenches 17 are arranged below the control terminal 13 and in a region of the chip laterally overlap therewith. The first trenches 14 and 16 are arranged in the active region 1-2 and for example do not extend or, respectively, only partially extend in said region of the chip laterally overlapping with the control terminal 13. E.g., if provided, the source trenches 16 do not extend into said region of the chip laterally overlapping with the control terminal 13, in accordance with an embodiment. Similarly, it may be provided that the second trenches 17 are exclusively arranged in the chip region laterally overlapping with the control terminal 13. For example, the second trenches 17 are separated from the first trenches 14, 16. Alternatively, it is also possible, as e.g. indicated in FIG. 3, that that the second trenches 17 seamlessly extend into the active region 1-2 to form there control trenches 14, as both the second trench electrodes 171 and the control trench electrodes 141 are electrically connected to the control terminal 13. In this latter case, the second trench electrode 171 and the control trench electrode 141 of the same trench may be constituted by a monolithic trench electrode. For example, as illustrated in FIG. 3, at least one of the control trenches 14 extends into the region laterally overlapping with the control terminal 13 and is connected to the control terminal 13 within the region laterally overlapping with the control terminal, e.g., based on one of the control trench contacts 145. Alternatively, these trenches are separated from each other, as illustrated in FIG. 5. Then, the control trench contacts 145 can for example be arranged so as to connect the gate runner 135 with the control trench electrodes (cf. FIG. 1A). Or non-illustrated gate fingers extend into the active region 1-2 such that the control trench electrodes 141 can be connected to the control terminal 13 within the active region 1-2.

Irrespective of which of the configuration described in the preceding paragraph is chosen, in accordance with an embodiment, it is provided that (cf. FIGS. 2-5) the first trenches 14, 16 in the active region 1-2 are arranged in accordance with a first average pitch p1 and that the second trenches 17 in the region of the chip laterally overlapping with the control terminal 13 are arranged in accordance with a second average pitch p2 different from the first average pitch p1.

For example, said two pitches p1 and p2 are independent from each other. This allows adjusting of, e.g., the second pitch p2 with regards to improvement of the ESD robustness.

In an embodiment, the second average pitch p2 is greater than the first average pitch p1, e.g., as exemplarily illustrated in FIG. 3 and FIG. 5.

Furthermore, it may be provided that the first pitch p1 in the active region 1-2 is constant and/or that the second pitch p2 in the region laterally overlapping the control terminal 13 is constant. Thus, in some embodiments, the pitches do not vary such that each pitch in the active region 1-2 is equal to the first average pitch p1 and each pitch in the region laterally overlapping the control terminal 13 is equal to the second average pitch p2.

The second average pitch p2 and the first average pitch p1 differ from each other by a ratio of at least ½. For example, the second average pitch p2 amounts to at least twice the first average pitch p1 or at most half of the first average pitch p1. For example, the ratio between the second average pitch p2 and the first average pitch p1 is equal to an integer or equal to the inverse of an integer. For example, the ratio between the second average pitch p2 and the first average pitch p1 is equal to a non-integer fraction greater than one or equal to the inverse of a non-integer fraction greater than one.

Each of the first trenches 14, 16 and the second trenches 17 may exhibit the same width (e.g., along the first lateral direction) and/or the same depth (along the vertical direction Z). E.g., each of the first trenches 14, 16 and the second trenches 17 are simultaneously produced based on the same processing steps. E.g., to achieve the pitch difference, only the employed masks are varied accordingly between the mask section relevant for the active region 1-2 and mask section relevant for the region laterally overlapping with the control terminal 13.

In an embodiment, the device 1 further comprises, cf. FIG. 4, in the region laterally overlapping with the control terminal 13, a doped region 105 of the second conductivity type, wherein the second trenches extend into the doped region 105. For example, the doped region 105 extends further along the vertical direction Z as compared to the second trenches 17. It may be provided that the doped region 105 does not extend into the active region 1-2. The doped region 105 may be electrically connected with the first load terminal 11. A transition between the doped region 105 and the drift region 100 may form a pn-junction. As indicated above, said pn-junction may be arranged below the bottoms of the second trenches 17.

E.g., based on the second trenches 17 and the optional doped region 105, an effective gate-source-capacitance may be defined. Furthermore, it may also be provided that one or more of the source trenches 16 that may be provided in the active region 1-2 also extend into the chip region below/laterally overlapping with the control terminal 13. Still, if one or more of the source trenches 16 extend into said region, the difference in average pitch, as described above, is maintained. At least the second trenches 17 are provided in said region, wherein these second trenches may be configured to improve the ESD robustness of the power semiconductor device 1.

In an embodiment, the second trenches 17 may also extend into the edge termination region 1-3. Again, even in this case, the difference in average pitch, as described above, is maintained. The second trenches 17 within the termination region 1-3 may either be oriented perpendicular or parallel to the first trenches 14, 16, particularly the control trenches 14. For example, some of the second trenches 17 within the termination region 1-3 may be oriented perpendicular and some of the second trenches 17 within the termination region 1-3 may oriented parallel to the first trenches 14, 16.

The semiconductor body 10 may be based on Si or on a wide bandgap material, such as SiC or GaN.

Presented herein is also a method of producing a power semiconductor device.

For example, according to a further embodiment, a method of producing a power semiconductor device comprises forming the following components: a semiconductor body with a drift region of a first conductivity type; a first load terminal at a first side of the semiconductor body; a second load terminal at a second side of the semiconductor body opposite to the first side, wherein the power semiconductor device is configured to conduct a load current between the first load terminal and the second load terminal; a control terminal at the first side configured to receive a control signal for controlling the load current; within an active region of the power semiconductor device at least partially surrounded by an edge termination region, first trenches laterally confining mesas for conducting the load current. The first trenches comprise control trenches electrically connected to the control terminal. The first trenches are arranged in accordance with a first average pitch. The device further comprises, in a region laterally overlapping the control terminal, second trenches, wherein the second trenches are arranged in accordance with a second average pitch different from the first average pitch and electrically connected to the control terminal.

Embodiments of the above-described method correspond to the embodiments of the power semiconductor device 1 described above. Accordingly, these embodiments of the method will not literally be described herein, but it is referred to the above.

E.g., as indicated above, the first trenches 14, 16 and the second trenches 17 are formed based on the same processing steps. Forming the first trenches 14, 16 and the second trenches 17 may comprise employing a mask, wherein the structure of the mask yields the difference between the second average pitch p2 and the first average pitch p1.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

What is claimed is:

1. A power semiconductor device, comprising:
a semiconductor body with a drift region of a first conductivity type;
a first load terminal at a first side of the semiconductor body;
a second load terminal at a second side of the semiconductor body opposite to the first side, wherein the power semiconductor device is configured to conduct a load current between the first load terminal and the second load terminal;
a control terminal at the first side configured to receive a control signal for controlling the load current;
within an active region of the power semiconductor device at least partially surrounded by an edge termination region, first trenches laterally confining mesas for conducting the load current, wherein the first trenches comprise control trenches electrically connected to the control terminal and are arranged in accordance with a first average pitch; and
in a region laterally overlapping the control terminal, second trenches arranged in accordance with a second average pitch different from the first average pitch and electrically connected to the control terminal.

2. The power semiconductor device of claim 1, wherein the second average pitch is greater than the first average pitch.

3. The power semiconductor device of claim 1, wherein the first pitch in the active region is constant and/or wherein the second pitch in the region laterally overlapping the control terminal is constant.

4. The power semiconductor device of claim 1, wherein the second average pitch and the first average pitch differ from each other by a ratio of at least ½.

5. The power semiconductor device of claim 1, wherein the first trenches and the second trenches exhibit a same width and/or a same depth.

6. The power semiconductor device of claim 1, further comprising:
in the region laterally overlapping with the control terminal, a doped region of the second conductivity type, wherein the second trenches extend into the doped region.

7. The power semiconductor device of claim 6, wherein the doped region is electrically connected with the first load terminal.

8. The power semiconductor device of claim 6, wherein the doped region extends further, with respect to a vertical direction, into the semiconductor body than the second trenches.

9. The power semiconductor device of claim 1, wherein the control terminal exhibits a pad configuration, and wherein a total lateral cross-sectional area of the control terminal amounts to a least 1% of a total lateral cross-sectional area of the active region.

10. The power semiconductor device of claim 1, wherein the first trenches comprise source trenches electrically connected to the first load terminal.

11. The power semiconductor device of claim 10, wherein at least one of the source trenches extends into the region laterally overlapping with the control terminal.

12. The power semiconductor device of claim 1, wherein the second trenches are configured to improve the electrostatic discharge (ESD) robustness of the power semiconductor device.

13. The power semiconductor device of claim 1, wherein at least one of the control trenches extends into the region laterally overlapping with the control terminal and is connected to the control terminal within the region laterally overlapping with the control terminal.

14. The power semiconductor device of claim 1, wherein the power semiconductor device is an IGBT or a MOSFET.

15. The power semiconductor device of claim 1, wherein the semiconductor body is based on a wide bandgap material.

16. A method of producing a power semiconductor device, the method comprising:
forming a semiconductor body with a drift region of a first conductivity type;
forming a first load terminal at a first side of the semiconductor body;
forming a second load terminal at a second side of the semiconductor body opposite to the first side, wherein the power semiconductor device is configured to conduct a load current between the first load terminal and the second load terminal;
forming a control terminal at the first side configured to receive a control signal for controlling the load current;
within an active region of the power semiconductor device at least partially surrounded by an edge termination region, forming first trenches laterally confining mesas for conducting the load current, wherein the first trenches comprise control trenches electrically connected to the control terminal and are arranged in accordance with a first average pitch; and
in a region laterally overlapping the control terminal, forming second trenches arranged in accordance with a second average pitch different from the first average pitch and electrically connected to the control terminal.

17. The method of claim 16, wherein the first trenches and the second trenches are formed based on same processing steps.

18. The method of claim 16, wherein forming the first trenches and the second trenches comprises employing a mask, wherein a structure of the mask yields the difference between the second average pitch and the first average pitch.

19. A power semiconductor device, comprising:
a semiconductor body with a drift region of a first conductivity type;
a first load terminal at a first side of the semiconductor body;
a second load terminal at a second side of the semiconductor body opposite to the first side, wherein the power semiconductor device is configured to conduct a load current between the first load terminal and the second load terminal;
a control terminal at the first side configured to receive a control signal for controlling the load current;
within an active region of the power semiconductor device at least partially surrounded by an edge termination region, first trenches laterally confining mesas for conducting the load current, wherein the first trenches comprise control trenches electrically connected to the control terminal and are arranged in accordance with a first average pitch; and
in a region laterally partially overlapping the edge termination region, second trenches arranged in accordance with a second average pitch different from the first average pitch and electrically connected to the control terminal.

20. The power semiconductor device of claim 19, wherein at least some or all of the second trenches are oriented parallel to the control trenches.

21. The power semiconductor device of claim 19, wherein at least some or all of the second trenches are oriented perpendicular to the control trenches.
